(19) United States
(12) Patent Application Publication
(10) Pub. No.: US 2010/0140084 A1
(43) Pub. Date: Jun. 10, 2010

(54) METHOD FOR PRODUCTION OF ALUMINUM CONTAINING TARGETS

(76) Inventors: Chi-Fung Lo, Fort Lee, NJ (US); Darryl Draper, Congers, NY (US); Paul Gilman, Suffern, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 12/330,996

(22) Filed: Dec. 9, 2008

(51) Int. Cl. C23C 14/34; B22F 3/24

(52) U.S. Cl. 204/298.13; 419/28

(57) ABSTRACT

A method of manufacturing a sputter target is provided which comprises mixing aluminum and at least one other metallic powder to form a powder blend, compressing said powder blend under significant force to achieve a pressed blank having a packing density of at least 50% of the theoretical density, heating the blank at a temperature less then the temperature which would form greater than an average of 25% inter-metallic phases in the blank under the conditions employed, rolling the blank to obtain at least 95% of the theoretical thickness of the blank, and bonding the blank to a suitable substrate. Also provided is a sputter target made from this method.

### BACKGROUND OF THE INVENTION

1. Field of the Invention

The present invention relates to sputter targets having improved physical structures and a method for their manufacture. More particularly, it relates to a method of making high performance metal sputter targets comprising aluminum and one or more other metals using a low temperature manufacturing method and the resulting targets that exhibit reduced inter-metallic phases.

2. Description of the Related Art

Sputtering deposition is a technique for depositing thin films by eroding or dislodging material from a target material using plasma or ion beam bombardment and then depositing the material onto a substrate. These deposition processes are known as physical vapor deposition (PVD) processes and are most often used in the semiconductor industry for the manufacture of integrated circuits and other electronic components. In these semiconductor applications, the targets are typically bimetallic compounds having precise specifications with high densities and high purities. The method of manufacture greatly affects the final target structure, and ultimately the thin film properties deposited on the electronic components.

Sputter targets having two or more metallic elements are commercially produced by either die casting or by powder metallurgy or both at elevated temperatures in order to melt or consolidate the powdered metals prior to forming the final target material. Several fabrication processes are taught in the art which typically involve placing metal powders in a mold and compressing the powder mix in a pressing apparatus under elevated temperatures and in controlled atmospheres. These metallic target materials are subsequently bonded to a suitable backing substrate such as a copper plate prior to commercial use. As described herein, the term target is used to describe both the metallic target material, e.g. the metallic compound, either alone or the metallic target material bonded to a substrate.

U.S. Pat. No. 6,042,777 is directed to method of fabricating inter-metallic sputter targets by blending the selected metal powders within a pressing apparatus, followed by heating the powder metals in a pressing apparatus at elevated temperatures to synthesize the powder blend while simultaneously applying pressure to achieve a final density of greater than 90% of the theoretical density. Such elevated temperatures are typically greater than 1000° C. depending on the metal chosen. U.S. Pat. No. 6,165,413 is directed to high density sputter targets prepared by pre-packing a powder bed by hot pressing or by vibrating metal plates followed by hot isostatic pressing at elevated temperatures. Again, the temperatures employed are typically above 1000° C.

However, the targets made by these high temperature processes (i.e., in excess of 1000° C. or even 1500° C.), will contain inter-metallic structures or phases which make the targets brittle and difficult to fabricate or otherwise machine. Such targets also tend to crack under high sputtering energy decreasing their effectiveness or useful life in PVD processes. Finally, targets containing inter-metallic structures or phases can introduce higher stress into the deposited film layer due to the greater difference in coefficients of thermal expansion between the deposited film and the substrate resulting in separation from or reduced adhesion to the backing substrate.

The present invention provides for an improved method for manufacturing aluminum containing sputter targets using a low temperature fabrication method. This low temperature method reduces the formation of inter-metallic structures or phases thereby making the target less prone to the undesirable physical characteristics of brittleness and cracking. Further, the present method provides economic advantage to both the manufacturer of the targets as well as the PVD end user since they are less costly to manufacture, have improved life and yield performance improvements in the sputtering process and, ultimately, in the final deposited film layer.

### SUMMARY OF THE INVENTION

The present invention provides a method for making sputter targets comprising mixing aluminum metallic powder and at least one other metallic powder to form a powder blend, compressing the powder blend under significant force to obtain a pressed blank having a packing density of at least 50% of the theoretical density, heating the blank at a temperature of less than the temperature which would form greater than an average of 25% inter-metallic phasing in the blank under the conditions employed, rolling the heated blank to obtain at least 95% of the theoretical density of the blank, and bonding the blank to a suitable substrate. Also provided are sputter targets made by the inventive method.

These sputter targets will comprise metallic compound materials containing aluminum and one or more metals bonded to a substrate and wherein the metallic compound material exhibits less than an average of about 25% of inter-metallic phases when examined using scanning electron microscopy (SEM) X-Ray diffraction (XRD) patterns.

### BRIEF DESCRIPTION OF THE DRAWINGS

FIG. 1 is a scanning electron microscope image of the microstructure of metallic and inter-metallic TiAl3 targets with phase identification by XRD patterns.

FIG. 2 is an XRD pattern analysis of TiAl3 mixed powder annealed at various temperatures ranging from 300° C. to 500° C.

FIG. 3 is a SEM comparison of TiAl3 microstructure rolled at 350° C. and at 400° C.

FIG. 4 is a SEM comparison of TiAl3 indentation morphology of TiAl3 using diamond indenter.

### DETAILED DESCRIPTION OF THE INVENTION

The present invention provides a method for the production of sputter targets made from aluminum and one or more elements using powder metallurgy whereby inter-metallic phases are reduced, and most preferably substantially avoided. According to this invention, the metallic powders are mixed to form a uniform blend, the powder blend is placed in a conventional die press and compressed to form a target blank and the blank is then heated at temperatures bellow the melting point of the metals employed to substantially avoid the formation of inter-metallic phases. After heating, the target material is bonded to a suitable backing substrate.

The metallic powders useful herein are comprised of aluminum and any metal or metal alloy suitable for use as a sputter target and subsequently for use in a process for depositing a thin film layer by PVD. The metal powders blends are combined to make metallic compounds from the compression of the metals under mechanical stress. The compression process can be conducted at ambient or slightly elevated temperatures, known as warm pressing.

As used herein, suitable powdered metals that can be used with aluminum include, but are not limited to, the metals Ti, Ni, Cr, Cu, Co, Fe, W, Si, Mo, Ta, Ru and combinations thereof as identified in the periodic table of elements. Common targets include alloys or combinations of these metals such as Ti—Al, Ni—Al, Cr—Al, Cu—Al, Co—Al, Fe—Al, and the like. These metallic compounds can also include multiple metals or metal alloys and this present invention includes binary, tertiary and quaternary metal systems. In other words, blends or combinations of two or more metals or metal alloys can be employed. Preferred are aluminum binary metallic powder blends containing Ti, Ni, Co and alloys thereof which will form metal compounds such as TiAlx, and NiAlx. Most preferred are binary systems represented by the formula TiAlx wherein x represent a number, from about 0.33 to about 3.0 (mole ratio) such as TiAl, Ti Al3 and Ti3Al.

The metallic powders used in this invention have an average particle size that range from about 0.5 μm to about 150 μm although larger particle sizes may be operable herein depending on the properties of the metal or metal alloy selected. Preferred are powders with average particle sizes ranging from 1 to 100 μm.

The amount of each metallic powder employed is dependent on the final desired composition and can vary from about 25% to about 75% by atomic percent (%). Mole ratio can be selected based on specific desired compounds such as 1 mole of titanium for 3 moles of aluminum to obtain a final TiAl3 structure or 1 mole of titanium and 1 mole of aluminum to obtain a final TiAl structure.

The metallic powders are mixed using conventional mixing apparatus such as ball mill or tubular blender and placed in a pressing apparatus to apply compression force to the powder blend. The mixing step is conducted for a time sufficient to achieve a substantially uniform mixture, typically from about 1 to about 20 hours. Any of the commonly available pressing devices can be used providing the pressure force placed on the powder bed can exert at least 0.5 kilo-pounds per square inch (ksi) or about 35 kilograms per square centimeter. The metallic powder blend is placed into die mold, such as a graphite die or low carbon steel die mold and then pressed under ambient temperatures. Alternatively, a hot isostatic pressing technique can be used wherein the temperature is not elevated above the temperature which begins the initiation of powder synthesis and the formation of inter-metallic phases, typically 450° C.

Once the metallic powder blend is loaded into the pressing die, it is compressed using a cold or warm pressing procedure. For example, it is compressed by applying pressure forces of between about 15 ksi and about 60 ksi at room temperature using cold-isostatic pressing or by applying pressure forces of between about 0.5 ksi and about 4 ksi in a warm process at temperatures from about 200° C. to about 450° C. using uniaxial pressing, both as conventionally known. The warm pressing is preferably conducted under a vacuum environment and the vacuum of the press machine is drawn to at least 0.0001 Torr prior to heating the pressing chamber. Generally, the pressure force is applied to the die for a period of at least 1 to 10 hours, preferably about 5 hours. The resulting pressed target blank will have a density above 50% of the theoretical density and preferably from about 60% to about 99% of the theoretical density.

The target blank is then placed in a containment vessel welded with an out-gassing tube, such as a low carbon steel fixture or suitable metal capsule. The vacuum in the vessel is drawn to less than 100 Torr prior to sealing the out-gassing tube and pre-heated the vessel at a temperature less than the temperature which would form greater than an average of 25% inter-metallic phases in the blank under the conditions employed, preferably less than 450° C., more preferably between 200° C. and 400° C., and most preferably between 300° C. and 350° C. for a time sufficient to ensure the target blank temperature becomes stable. The pre-heated target blank is then pressed by conventional means such as by rolling, forging, hot-isostatic pressing or other known techniques to reduce the thickness of the blank by a suitable amount to obtain a density of at least 95% of the theoretical density of the blank, preferably by more than 97% and most preferred to about 99%. Preferably, the blank is rolled while still at elevated temperatures. Accordingly, the resulting target blank will have less than an average of 25% inter-metallic phases, and preferably less than an average of 10% inter-metallic phases. It is most preferred to utilize temperatures which will result in the target blank, and the final target, being substantially free of inter-metallic structures under the conditions employed.

From about 95% to about 99% of theoretical density can be achieved at temperature above 200° C. by rolling or forging the preheated blank to obtain at least a 50% thickness reduction and preferably, at temperatures between 300° C. and 450° C. Above about 450° C. for the AlTi materials, significant inter-metallic phases are observed, such as above an average of 25% of the target material. Most preferred for Ti/Al targets that are substantially free of inter-metallic phases, the temperature of the warm pressing step will be less than 400° C.

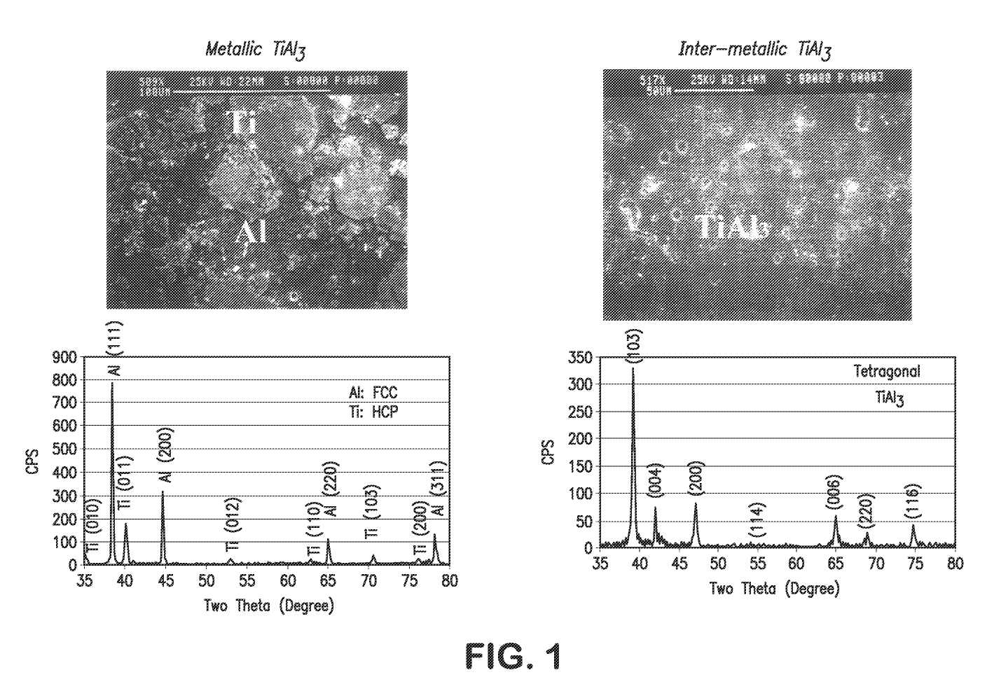

Sputter targets made by the present process are metallic compounds that do not contain significant amounts of inter-metallic phases in the crystalline orientation when compared to sputter target made from prior hot pressing techniques in which temperatures above 450° C. are typically used while the metals were synthesized either prior to or during the compression step. Inter-metallic structures are composed of finite proportions of two or more elemental metals in an organized crystalline pattern, rather than by a continuously variable proportion such as in solid solutions. These compounds are the result of the diffusion of one metal into at least one other metal when the first metal exhibits phase changes resulting in inter-diffusion between the metals. As discussed, the resulting compounds are more brittle and the crystal structure is observed to be different from the crystal structure of the individual metals. As used herein, inter-metallic phases are intended to mean solid structures or phases containing aluminum and one or more metallic elements whose crystal structure differs from that of the individual constituent metals and the microstructures exhibit a single phase when examined under SEM. FIG. 1 compares the microstructure between inter-metallic TiAl₃ and metallic TiAl₃ by examination under SEM and XRD patterns. The samples were made by cold-pressed followed by warm-rolled at 300° C. The inter-metallic TiAl₃ shows tetragonal crystalline structure, TiAl₃, while the metallic TiAl₃ shows hexagonal close-packed crystalline structure for Ti, and a face center cubic crystalline structure for Al. The SEM illustrates the presence of substantial inter-metallic phasing illustrated by the more uniform light gray colored pattern.

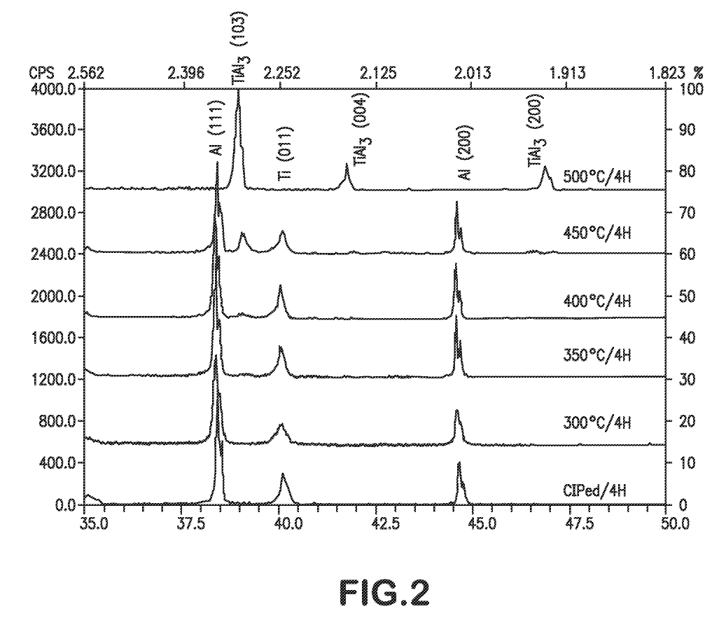

Corresponding XRD patterns where examined for metallic powder mixes containing 1 mole of Ti and 3 moles of Al to form a TiAl3 structure after heating. Samples of the powder blend were heated at temperatures of 300° C., 350° C., 400° C., 450° C., 500° C. in a containment vessel for 4 hours to simulate the pressing step. Each sample was removed and examined by comparing the XRD patterns. FIG. 2 shows the change of XRD patterns from a cold-pressed sample at ambient temperatures and at the various temperatures identified up to 500°. Only the Ti and Al metallic phases were detected for the samples heated up to about 350° C. A small peak intensity of TiAl₃ (103) was detected at 400° C. A more significant increase in peak intensity of TiAl₃ (103) was observed for the sample heated at 450° C. The XRD results show that the inter-metallic phase is generated at large amounts in excess of an average of 25% of the target material at temperatures of between 450° C. and 500° C.

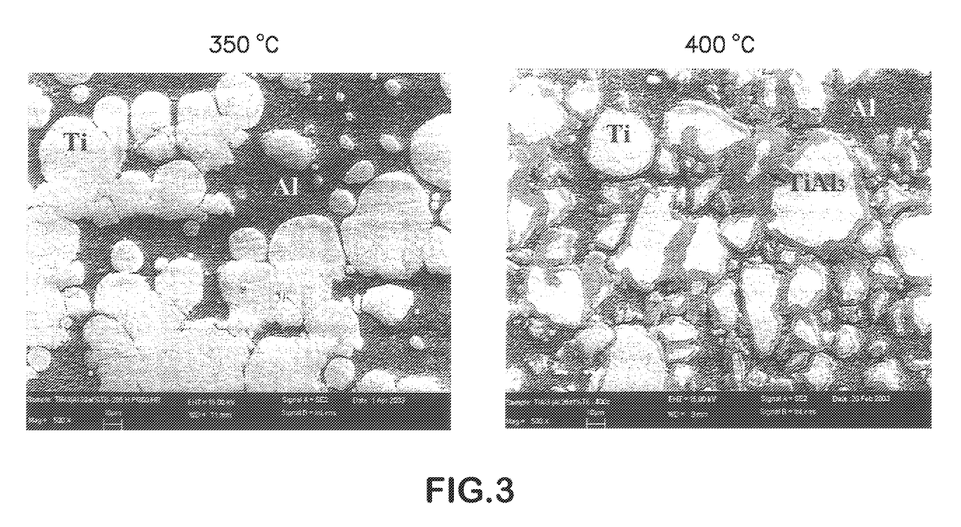

As explained above, the presence of an inter-metallic structure or phases in the target structure is undesirable as such phases tend to make the target brittle and prone to cracking during machining, cutting or other further processing steps. Thus it is desirable to limit the degree or extent of inter-metallic phasing which occurs during the manufacture of the target requiring controlling the temperatures used. While some degree of inter-metallic phasing can be present in the targets of the present invention, it is preferred to limit this to an amount of less than an average of about 25% of the overall target structure. The degree of inter-metallic phasing is determined by examining the XRD pattern and SEM image of target material. The percent inter-metallic phasing derived by XRD measurement is confirmed by the review of the microstructure as observed by the SEM image taken at a magnification of 500×. FIG. 3 shows the microstructures of TiAl3 rolled at 350° C. and 400° C., respectively as taken by SEM at a magnification of 500×. The percentage of inter-metallic structure is about 0% and approaching 25%, respectively. The percent of different phases were calculated using an image analyzer to measure the percent of each phase showing on the micrograph. Thus, the targets made by the process of the present invention will have less than an average of about 25% inter-metallic phasing, preferably less than an average of 10% and most preferably will be substantially free of inter-metallic phases when examined under XRD analysis. Preferably, the warm target blank within a metal capsule is removed from heating furnace and then rolled to obtain at least a 50% thickness reduction. In this step, 10% to 20% thickness reduction per pass is generally applied. The rolled piece is re-heated for 5 minutes minimum after each rolling pass, preferably 10 minutes to ensure the capsule has been re-heated to furnace set temperature.

The final density of the rolled target blank is greater than 95% of the theoretical density. The preferred density depends on the metals or metal alloys used, the ratio of metals and whether there is a binary, tertiary or multiply metal structure. For binary structures containing Al and Ti, the density is preferably at least 97% of the theoretical density and most preferably about 99%.

Normally, the final target blank will be machined prior to being bonded to selected backing or substrate such as copper, molybdenum, iron, or combinations thereof. The machining can be conducted on a lathe or other conventional cutting tool to obtain the desired size and shape. The target blank will be bonded to the substrate using conventional adhesives, solders or other bonding techniques. Common indium or indium/tin solders can be used for this purpose.

### EXAMPLE 1

One mole of aluminum powder (162 grams) having an average particle size of 20 μm and one mole of titanium powder (287 grams) having an average particle size of 35 μm were blended for 3 hours using a ball milling can to obtain a uniform blend. The blended powder was then loaded into a steel die mold press and pressed at room temperature using 100 ksi of pressure for 1 minute to form a 4 inch (10.16 cm) by 4 inch (10.16 cm) by 0.54 inch (1.37 cm) blank. The density of the pressed blank was measured to be 3.18 gm/cc by weight/volume method which corresponds to about 87% of the theoretical density. To avoid oxidation during rolling, the pressed blank was placed into a low carbon steel capsule welded with a low carbon steel tube. The tube was sealed by torch after the capsule was evacuated to vacuum with 1 mTorr. The capsule was then heated at 350° C. for one hour in heating furnace and subsequently rolled on a rolling mill to obtain a 5.4 inch (13.72 cm) by 5.4 inch (13.72 cm) by 0.27 inch (0.69 cm) rolled blank representing a thickness reduction of about 50%. The final blank density was measured to be 3.54 gm/cc which corresponds to a theoretical density of 97% for TiAl. The blank was machined to a 4 inch (10.16 cm) by 0.25 inch (0.64 cm) diameter using a mechanical lathe with a tungsten point tool and bonded to a Cu backing plate with In/Sn solder using a solder gun to form the sputter target.

### EXAMPLE 2

Example 1 was repeated following the procedure described above except 259 grams of the aluminum powder was mixed with 154 grams of titanium powder. The average particle size was as described above. The pressed blank was 4 inch (10.16 cm) by 4 inch (10.16 cm) by 0.52 inch (1.32 cm) and had a density of 3.02 g/cc which corresponds to about 95% of the theoretical density. The heated blank was rolled again to achieve a 50% reduction (5.4 inch (13.72 cm) by 5.4 inch (13.72 cm) by 0.27 inch (0.69 cm)), machined as above and bonded to a Cu backing. The final blank had a final density of 3.18 gm/cc corresponding to a theoretical density of 100% for TiAl3.

### EXAMPLE 3

Example 2 was repeated following the procedure described above except the powder blend was packed in a rubber capsule and pressed by cold isostatic pressing applying 20 ksi of pressure in a pressure vessel using water as the pressing media. The pressed blank was 4.8 inch (12.19 cm) by 4.8 inch (12.19 cm) by 0.39 inch (0.99 cm) and had a density of 2.77 gm/cc which corresponds to about 87% of the theoretical density. The blank was heated in this example in a hot isostatic press by applying 20 ksi at 350° C. for 3 hours to achieve 4.7 inch (11.94 cm) by 4.7 inch (11.94 cm) by 0.37 inch (0.94 cm) and had a final density of 3.08 gm/cc corresponding to a theoretical density of 97% for TiAl₃. The blank was machined as above and bonded to a Cu backing.

Each or the sputter targets were placed into a physical vapor deposition tool to sputter the target material and deposit to the wafers.

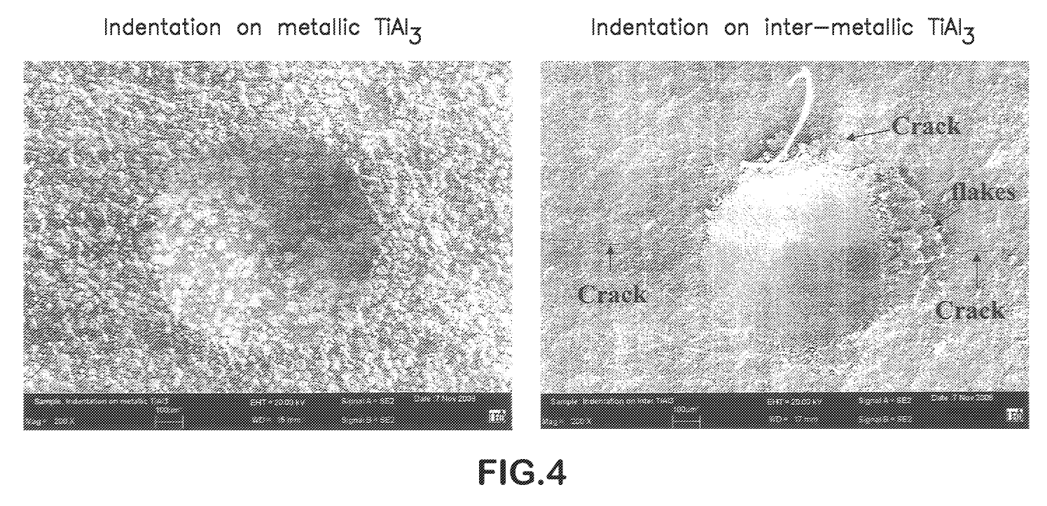

Comparing to the films deposited from inter-metallic targets, the films deposited from the metallic target showed lower hardness and elastic modulus by MTS nano-indentation measurement. FIG. 4 shows the morphologies of indentation by applying diamond indenter with pressure of 30 kg and 60 kg for the metallic and inter-metallic TiAl₃ targets, respectively. No crack around the indentation for the metallic TiAl₃ target, while several cracks were generated around the indentation of the inter-metallic TiAl₃ target. The indentation test indicates that the target containing inter-metallic phases is more brittle than the target containing the metallic phases for the TiAl₃samples. It should be apparent to those skilled in the art that the subject invention is not limited by the examples provided herein which have been provided to merely demonstrate the operability of the present invention. The selection of target materials, equipment and other process conditions can be determined from the specification without departing from the sprit of the invention as herein disclosed and described. The scope of this invention includes equivalent embodiments, modifications, and variations that fall within the scope of the attacked claims.

1. A method for making sputter targets comprising:
mixing an aluminum metallic powder and at least one other metallic powder to form a powder blend,
compressing said powder blend under significant force to achieve a pressed blank having a packing density of at least 50% of the theoretical density,
heating said pressed blank at a temperature less than the temperature which would form greater than an average of 25% inter-metallic phases in said pressed blank under the conditions employed, rolling said pressed blank to obtain a density of at least 95% of the theoretical density of said blank,
and bonding said blank to a substrate.

2. The method of claim 1 wherein the powder blend is compressed at a temperature of less than about 450° C.

3. The method of claim 2 wherein said powder blend is compressed at a temperature between 200° C. and 400° C. at compression pressures from about 0.5 to about 4 ksi for 1 to 10 hours.

4. The method of claim 1 wherein said pressed blank has at least a 50% thickness reduction.

5. The method of claim 1 wherein said other metallic power is selected from the group Ti, Ni, Cr, Cu, Co, Fe, W, Si, Mo, Ta, Ru, and combinations thereof.

6. The method of claim 5 wherein said target is a metal compound is represented by the formula TiAlx wherein x is a number from about 0.33 to about 3.0.

7. A sputter target made by the process of:
mixing an aluminum metallic powder and at least one other metallic powders selected from the group consisting of Ti, Ni, Cr, Cu, Co, Fe, W, Si, Mo, Ta, Ru, and combinations thereof to form a powder blend,
compressing said powder blend under significant force to achieve a pressed blank having a packing density of at least 50% of the theoretical density,
heating said pressed blank at a temperature less than the temperature which would form greater than an average of 25% inter-metallic phases in said pressed blank under the conditions employed to obtain a heated blank,
rolling said heated blank to obtain a density of at least 95% of the theoretical density of said blank,
and bonding said blank to a substrate.

8. The target of claim 7 wherein said powder blend comprises an Al binary metallic powder containing Ti, Ni, Co and alloys thereof.

9. The target of claim 8 wherein said powder blend is compressed at a temperature between 200° C. and 400° C. at compression pressures from about 0.5 to about 4 ksi for 1 to 10 hours.

10. The target of claim 9 wherein the compression is conducted under a vacuum environment.

11. The target of claim 7 being substantially free of inter-metallic phases.

12. A sputter target comprised of a metallic compound material containing aluminum and one or more metals wherein said metallic compound material exhibits less than an average of 25% of inter-metallic phases and a density of at least 95% of the theoretical density.

13. The target of claim 12 wherein said metallic compound material comprised Al and a metal selected from Ti, Ni, Cr, Cu, Co, Fe, W, Si, Mo, Ta, Ru, and combinations thereof.

14. The target of claim 13 wherein said metallic compound material consists of an Al binary metallic compound containing Ti, Ni, Co and alloys thereof.

15. The target of claim 14 wherein the target is represented by the formula TiAlx wherein x is a number from about 0.33 to about 3.0.

16. The target of claim 15 wherein said density is at least 97% of the theoretical density.

17. The target of claim 16 wherein said packing density is about 99% of the theoretical density.

18. The target of claim 12 wherein said metallic compound material has less than an average of about 10% inter-metallic phases.

19. The target of claim 12 wherein said metallic compound material is substantially free of inter-metallic phases.
